(19) United States
(12) Patent Application Publication
(10) Pub. No.: US 2025/0183179 A1
(43) Pub. Date: Jun. 5, 2025

(54) PASSIVE STRUCTURES IN EMBEDDED BRIDGE ARCHITECTURES

(71) Applicant: Intel Corporation, Santa Clara, CA (US)

(72) Inventors: Brandon C. MARIN, Gilbert, AZ (US); Mohamed R. SABER, College Station, TX (US); Srinivas Venkata Ramanuja PIETAMBARAM, Chandler, AZ (US); Gang DUAN, Chandler, AZ (US); Jeremy D. ECTON, Gilbert, AZ (US); Suddhasattwa NAD, Chandler, AZ (US); Benjamin DUONG, Phoenix, AZ (US); Bohan SHAN, Chandler, AZ (US); Sashi S. KANDANUR, Phoenix, AZ (US); Cary KULIASHA, Mesa, AZ (US); Shruti SHARMA, Chandler, AZ (US); Mollie STEWART, Lake Oswego, OR (US); Rahul N. MANEPALLI, Chandler, AZ (US); Kristof DARMAWIKARTA, Chandler, AZ (US)

(21) Appl. No.: 18/528,222

(22) Filed: Dec. 4, 2023

(51) Int. Cl. H01L 23/538; H01L 23/64

(52) U.S. Cl. CPC H01L 23/5381; H01L 23/642; H01L 23/645

(57) ABSTRACT

Embodiments disclosed herein comprise bridge dies with embedded passive components. In an embodiment, the bridge die is an apparatus that comprises a substrate with a via at least partially through a thickness of the substrate. In an embodiment, the via is electrically conductive. In an embodiment, a shell is provided around a perimeter of the via, and the shell is a different material than the via.

### BACKGROUND

Computing architectures continue to scale to smaller form factors while pushing towards higher bandwidths and computing capacity. One solution for enabling such design goals is to use chiplet architectures. Instead of a single large chip, a plurality of smaller chiplets are stitched together by a bridge. When the bridge is embedded in the underlying package substrate, the bridge may be referred to as an embedded bridge solution. Existing bridge solutions typically do not allow for power to pass through a thickness of the bridge. Instead, traces are routed over the bridge in order to provide power within the footprint of the bridge. This complicates routing and increases the length of the power delivery path, which can impact performance.

Accordingly, it has been suggested that vias be provided through the bridge in order to route power directly through a thickness of the bridge. Such architectures are promising, but have integration and performance issues that should be addressed. For example, the power delivery through the bridge is often limited by current carrying capacity of the vias through the bridge. Integration with pads underlying the bridge is also an issue in some instances.

### BRIEF DESCRIPTION OF THE DRAWINGS

FIG. 1A is a cross-sectional illustration of a package substrate with an embedded bridge that includes power routing that wraps around the bridge, in accordance with an embodiment.

FIG. 1B is a cross-sectional illustration of a package substrate with an embedded bridge that includes power routing through a thickness of the bridge, in accordance with an embodiment.

FIG. 2A is a cross-sectional illustration of a bridge that includes inductor structures through a thickness of the bridge, in accordance with an embodiment.

FIG. 2B is a cross-sectional illustration of a bridge that includes inductor structures with vias that have tapered sidewalls, in accordance with an embodiment.

FIG. 2C is a cross-sectional illustration of a bridge with routing layers over the bridge, in accordance with an embodiment.

FIG. 2D is a cross-sectional illustration of a bridge with integrated capacitor structures, in accordance with an embodiment.

FIGS. 3A-3F are cross-sectional illustrations depicting a process for forming a bridge with integrated passive structures, in accordance with an embodiment.

FIG. 4 is a cross-sectional illustration of a bridge with an integrated passive structure that includes inductors connected in series, in accordance with an embodiment.

FIG. 5 is a cross-sectional illustration of a bridge with an integrated passive structure that includes capacitors connected in parallel, in accordance with an embodiment.

FIGS. 6A-6D are cross-sectional illustrations depicting a process for forming a package substrate with an embedded bridge that includes passive structures, in accordance with an embodiment.

FIG. 7 is a cross-sectional illustration of an electronic system that includes an embedded bridge with passive structures, in accordance with an embodiment.

FIG. 8 is a schematic of a computing device built in accordance with an embodiment.

### EMBODIMENTS OF THE PRESENT DISCLOSURE

Described herein are electronic systems, and more particularly, architectures for coupling an embedded bridge with integrated passive devices to a package substrate, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, embedded bridge architectures have been used in order to implement device scaling which can lead to smaller devices while maintaining or improving device performance. However, continued scaling of embedded bridge structures has led to greater issues with electrically coupling the bridge to other features within the package substrate.

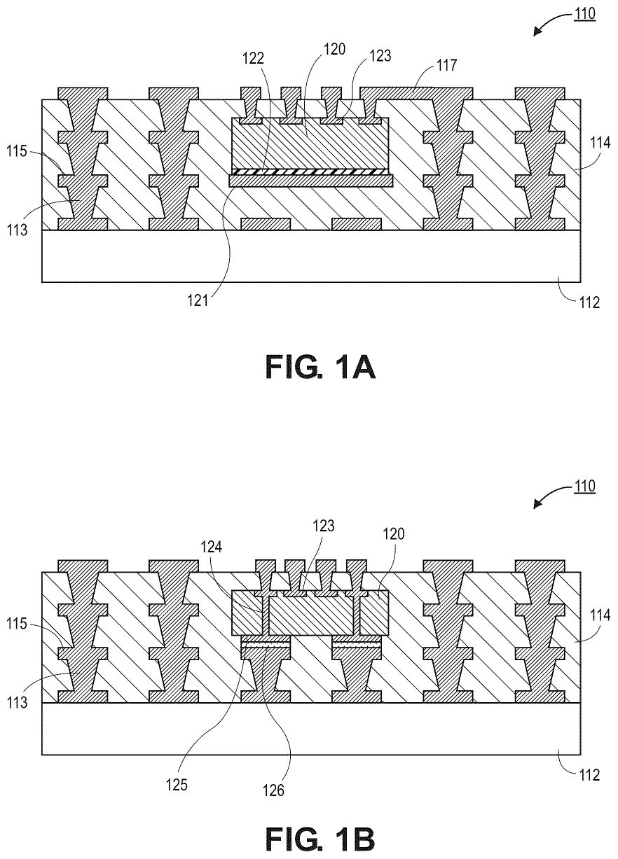

An example of a typical embedded bridge structure is shown in FIG. 1A. In FIG. 1A, a cross-sectional illustration of a package substrate 110 is shown, in accordance with an embodiment. In an embodiment, the package substrate 110 comprises a core 112. The core 112 may be any suitable core material. For example, the core 112 may comprise an organic core with glass fiber reinforcement or the core 112 may comprise a substantially solid glass layer. While shown as a monolithic structure, the core 112 typically includes electrically conductive vias that pass through a thickness of the core 112. In an embodiment, buildup layers 114 may be provided over the core 112. Buildup layers 114 may also be provided over the bottom of the core 112. The bottom portion of the package substrate 110 is omitted from FIG. 1A for clarity since the bridge 120 is located in the top portion of the package substrate 110. The buildup layers 114 may comprise an organic dielectric material. For example, multiple dielectric layers may be laminated over each other in order to form the larger structure of the buildup layers 114. In an embodiment, the buildup layers 114 may comprise electrically conductive routing, such as vias 113, pads 115, traces 117, and the like. The electrically conductive routing may comprise copper, copper alloys, or other metallic materials.

In an embodiment, the bridge 120 is embedded within the buildup layers 114. The bridge 120 may also be referred to as a “die” or a “bridge die” in some embodiments. The bridge 120 may be a dimensionally stable material. For example, the bridge 120 may comprise silicon, other semiconductor materials, a ceramic, glass, or the like. In an embodiment, electrically conductive routing (e.g., traces, pads, etc.) may be provided on the bridge 120. For example, pads 123 are shown in FIG. 1A. In some instances, the routing may be provided in back-end-of-line (BEOL) layers (not shown) over the dimensionally stable base material (e.g., silicon). The BEOL layers may include dielectric materials, such as silicon oxide, silicon nitride, organic dielectrics, and the like. The dimensional stability of the bridge 120 allows for fine line and space (L/S) dimensions in order to provide electrical coupling between overlying dies (not shown in FIG. 1A). In an embodiment, the bridge 120 may be provided over an etchstop layer 121. The etchstop layer 121 may comprise copper or the like. The bridge 120 may be secured to the etchstop layer 121 by an adhesive 122 or the like.

In the illustrated embodiment, there are no vias through a thickness of the bridge 120. Accordingly, power is not able to be routed through the bridge 120. Instead, power is provided in a path that passes adjacent to a sidewall of the bridge 120. Once above the level of the top surface of the bridge 120, a trace 117 can route power into the footprint of the bridge 120. This increases the length of the power delivery path and decreases performance. Additionally, the lateral routing makes routing within the package substrate 110 more complicated.

Accordingly, embodiments disclosed herein may utilize a bridge 120 that includes vias 124. An example of such an embodiment is shown in FIG. 1B. As shown, the vias 124 pass through at least a portion of the thickness of the bridge 120. Pads 125 at the bottom of the bridge 120 are coupled to pads 123 at the top of the bridge 120 through the vias 124. In an embodiment, the bottom pads 125 are coupled to pads 115 in the buildup layers 114 through a solder 126 or the like. In order to make the necessary electrical connections, the thickness variation of the buildup layers 114 needs to be low.

When a glass core 112 is used, thickness variation is typically improved. The improvement is maximized as the bridge 120 is moved closer to the surface of the glass core 112. That is, reducing the thickness of the buildup layers 114 between the bridge 120 and the core 112 is beneficial. However, as the bridge 120 is moved closer to the core 112, potential for damaging the core 112 is increased. The core 112 is brittle and is prone to cracking or other damage. Accordingly, some amount of buffer layer is currently necessary between the core 112 and the bottom of the bridge 120.

The solder 126 between the bridge 120 and the pad 115 on the buildup layers 114 may result in several issues. For example, the solder 126 has poor current carrying capability, which leads to a less than desirable IMAX value. Additionally, underfill may be needed around the solder 126. Due to a tight pitch between interconnects, voids may be formed. Voids negatively impact product reliability. Solder 126 also increases the standoff height of the device, and the cavity to accommodate the bridge 120 needs to be deeper.

Therefore, embodiments disclosed herein provide improved interconnect architectures in order to address these issues. In one embodiment, electrical performance of the bridge is improved through the integration of electrically passive components or structures. An electrically passive component (sometimes referred to simply as a “passive”) may include any traditional passive device used in electrical circuits, such as, but not limited to, capacitors, inductors, resistors, or the like. In some instances, the passives embedded in the bridge are part of an electrical path between a bottom of the bridge and a top of the bridge. That is, the passives may function as a via or a portion of a via in order to pass current through a thickness of the bridge. The use of passive devices can control or improve different electrical characteristics of the bridge. For example, in the case of an inductor, the Imax value can be improved. Particularly, increasing the inductance through the use of inductors can improve performance when dealing with high frequency impedance issues.

Embodiments disclosed herein include the use of passives in any combination or arrangement. In one instance, a single passive device can be used as a via between pads on the top and bottom of the bridge. In other instances, multiple passives can be linked together in series, in parallel, or in series and in parallel in order to provide increased inductance or capacitive values. The passive devices included herein may sometimes be referred to as being deep trench structures. That is, the passives are oriented in a predominately vertical position within a trench or hole into or through the bridge.

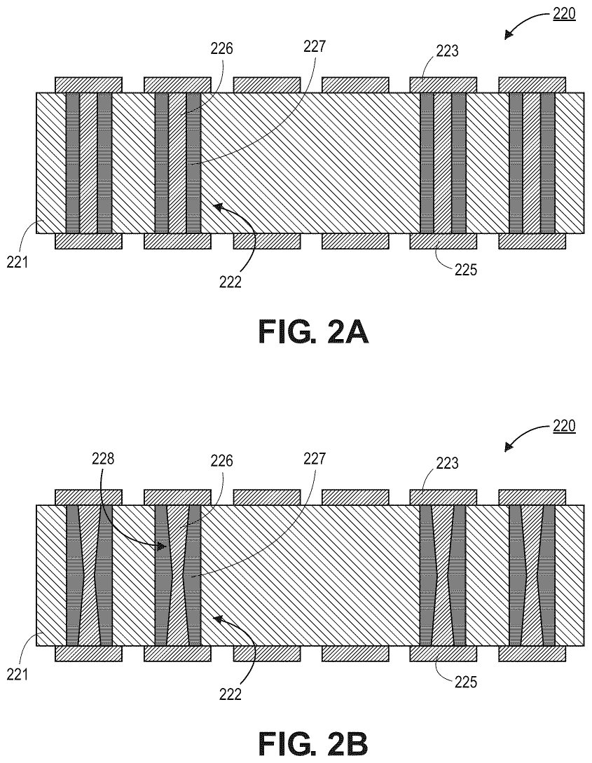

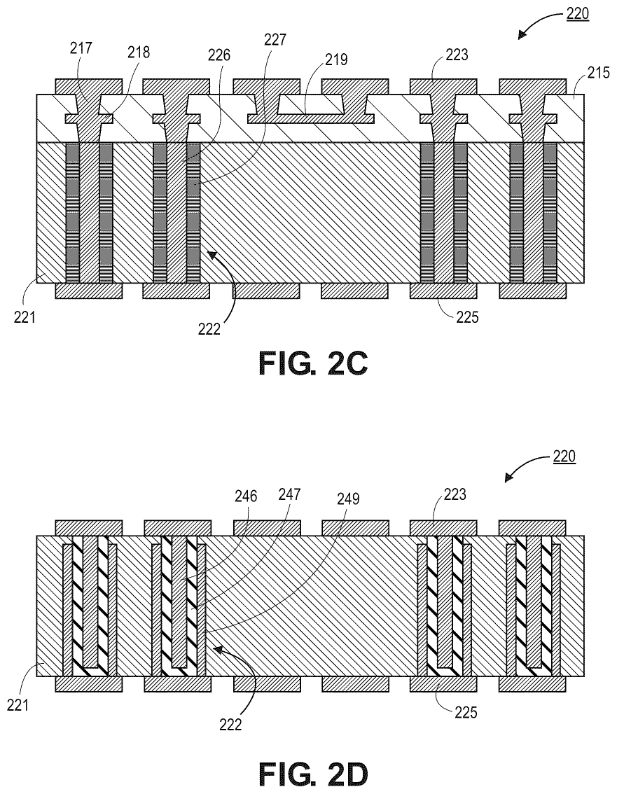

Referring now to FIGS. 2A-2D, a series of cross-sectional illustrations depicting different bridge embodiments is shown, in accordance with an embodiment. The bridges depicted in FIGS. 2A-2D may be integrated into package substrates similar to those described in greater detail above. That is, the bridges can be insert into cavities formed into the buildup layers of a package substrate.

Referring now to FIG. 2A, a cross-sectional illustration of a bridge 220 is shown, in accordance with an embodiment. In an embodiment, the bridge 220 comprises a substrate 221. The substrate 221 may comprise any material suitable for forming high density routing in order to communicatively couple chiplets together. Properties suitable for such applications include, but are not limited to, one or more of high planarity, high strength, a patternable material, and/or a dimensionally stable material. For example, the substrate 221 may comprise a silicon die or any other semiconductor die. Other materials for the substrate 221 may include glass, ceramic, or the like.

In an embodiment, the bridge 220 may include pads 225 on a bottom surface of the substrate 221. The pads 225 in FIG. 2A are shown as extending out from the bottom surface of the substrate 221. In other embodiments, the pads 225 may be flush with the bottom surface of the substrate 221. That is, a bottom surface of the pads 225 may be substantially coplanar with the bottom surface of the substrate 221. Similarly, pads 223 may be provided at a top surface of the substrate 221. The pads 223 may extend out from the top surface of the substrate 221 (as shown), or the pads 223 may be flush with the top surface of the substrate 221. In an embodiment, the pads 225 and the pads 223 may include any suitable electrically conductive material or materials. For example, the electrically conductive material may include copper or an alloy of copper. Seed layers, diffusion barrier layers, oxidation mitigation layers, or the like may also be incorporated in the pads 223 and/or the pads 225.

In an embodiment, passive components 222 may provide electrical coupling between pads 225 and pads 223. The passive components 222 may be considered via structures in some instances. In the particular embodiment shown in FIG. 2A, the passive components 222 may be inductors. The passive components 222 may comprise a via 226 and a shell 227 around the via 226. The via 226 may be an electrically conductive material, such as copper or an alloy of copper. The shell 227 may be a magnetic material. The magnetic material may comprise a solid metallic structure, a paste or epoxy with magnetic filler particles, or any other structure or composite that results in the generation of a magnetic field. In a particular embodiment, the shell 227 may comprise cobalt and iron (e.g., CoFe), though other magnetic element(s) may also be used. For example, the shell 227 may comprise one or more of iron, cobalt, nickel, neodymium, or the like.

The shell 227 may have an outer surface and an inner surface. The outer surface may contact the substrate 221, and the inner surface may contact the via 226. In some instances, a buffer layer, a seed layer, or another thin layer may be provided between the via 226 and the inner surface of the shell 227. A thickness of the shell 227 between the inner surface and the outer surface may be up to approximately 30 μm. For example, the thickness of the shell 227 may be between approximately 0.5 μm and approximately 15 μm in some embodiments. Though, thicker or thinner shells 227 may also be used in some embodiments.

In the illustrated embodiment, the height of the shell 227 is substantially equal to the height of the via 226. In other embodiments, the height of the shell 227 may be less than the height of the via 226. In such instances, one or both ends of the via 226 may extend past the top and/or bottom of the shell 227. Further, the embodiment shown in FIG. 2A includes passive components 222 that extend entirely through a thickness of the substrate 221. In other instances, the passive components 222 may be shorter than the height of the substrate 221.

Referring now to FIG. 2B, a cross-sectional illustration of a bridge 220 is shown, in accordance with an additional embodiment. In an embodiment, the bridge 220 in FIG. 2B is substantially similar to the bridge 220 in FIG. 2A, with the exception of the structure of the passive components 222. In FIG. 2A, the passive components 222 have vias 226 that are cylindrical with a substantially vertical sidewall. In FIG. 2A, the vias 226 have non-uniform diameters. For example, the embodiment shown in FIG. 2B includes vias 226 that have an hourglass shaped cross-section. That is, a sidewall 228 of the via 226 is tapered (i.e., non-vertical). While a double taper is shown in FIG. 2B, other embodiments may include a single taper (e.g., the top of the via 226 may be wider than a bottom of the via 226). The tapered structure of the via 226 may be the result of patterning processes used to form the passive component 222, as will be described in greater detail below. The shell 227 may conform to the shape of the sidewall 228. Accordingly, the shell 227 may have an outer surface that is not parallel to an inner surface.

Referring now to FIG. 2C, a cross-sectional illustration of a bridge 220 is shown, in accordance with an additional embodiment. The bridge 220 may include a substrate 221 with passive components 222 through a thickness of the substrate 221. Pads 225 are provided at a bottom of the substrate 221. In an embodiment, a routing structure 215 may be provided over the top of the substrate 221. The routing structure 215 may be a dielectric material through which electrical routing (e.g., vias 217, pads 218, traces 219, etc.) is provided. The routing structure 215 may comprise an organic dielectric, silicon dioxide, silicon nitride, or the like. In some instances, the routing structure 215 may be considered a BEOL structure.

The routing structure 215 may provide electrical connections between the passive components 222 and the pads 223 at the top of the routing structure 215. For example, vias 217 and pads 218 are provided between passive components 222 and the pads 223. The routing structure 215 may also provide the high density routing used to communicatively couple chiplets (not shown) together. For example, the two central pads 223 are electrically coupled together by a trace 219.

Referring now to FIG. 2D, a cross-sectional illustration of a bridge 220 is shown, in accordance with an additional embodiment. The bridge 220 may comprise a substrate 221 with pads 225 on the bottom and pads 223 on the top. In an embodiment, passive components 222 are embedded in the substrate 221. The passive components 222 may be oriented in a vertical position to pass current through a thickness of the substrate 221. That is, the passive components 222 may be at least part of the vertical electrical path between pads 225 and pads 223.

In an embodiment, the passive components 222 may comprise capacitor structures. More particularly, the passive components 222 may be deep trench capacitor structures. In an embodiment, the passive components 222 may comprise a first electrode 246, an interface layer 247, and a second electrode 249. The first electrode 246 and the second electrode 249 may comprise electrically conductive material, such as copper, a copper alloy, or the like. In an embodiment, the first electrode 246 may be a solid slug of material, such as one having a cylindrical shape. The second electrode 249 may be a shell with an outer surface contacting the substrate 221 and an inner surface contacting the interface layer 247. In an embodiment, the first electrode 246 and the second electrode 249 may be electrically coupled to different pads. For example, the first electrode 246 may be coupled to a pad 223, and the second electrode 249 may be coupled to a pad 225.

In an embodiment, the interface layer 247 electrically isolates the first electrode 246 from the second electrode 249. The interface layer 247 may be a dielectric material. In some embodiments, the interface layer 247 is a high-k dielectric material. As used herein, a “high-k dielectric material” refers to a material with a dielectric constant that is equal to or higher than the dielectric constant of silicon dioxide (which has a k-value of around 3.9). Some elements that may be found in the material of the interface layer 247 may include, but are not limited to, silicon, hafnium, zirconium, nitrogen, oxygen, lanthanum, aluminum, tantalum, titanium, barium, strontium, yttrium, scandium, zinc, niobium, or lead.

In an embodiment, a cross-sectional view of the passive component 222 may illustrate the interface layer 247 as having a U-shaped cross-section. For example, the interface layer 247 may have vertical portions along sidewalls of the first electrode 246 and a horizontal portion below the first electrode 246 that connects the vertical portions together. The interface layer 247 may have a height that extends from the top of the substrate 221 to a bottom of the substrate 221. One or both of the first electrode 246 and the second electrode 249 may have heights that are shorter than the height of the interface layer 247.

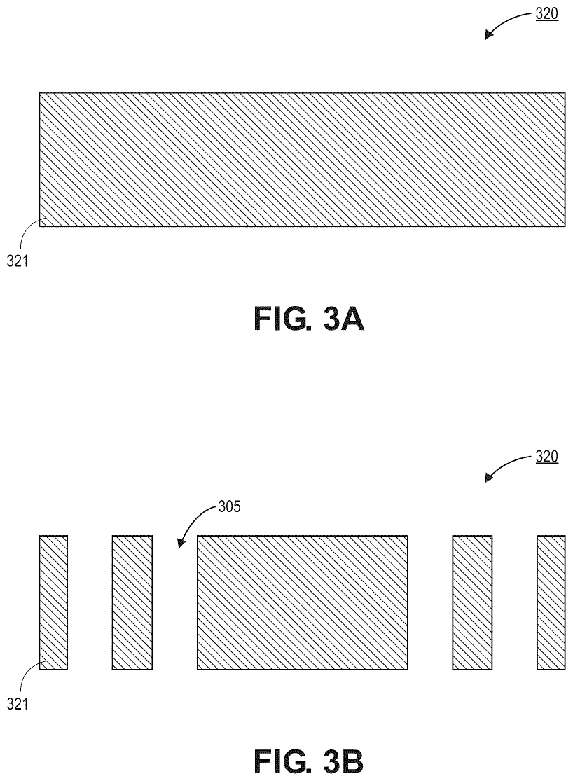

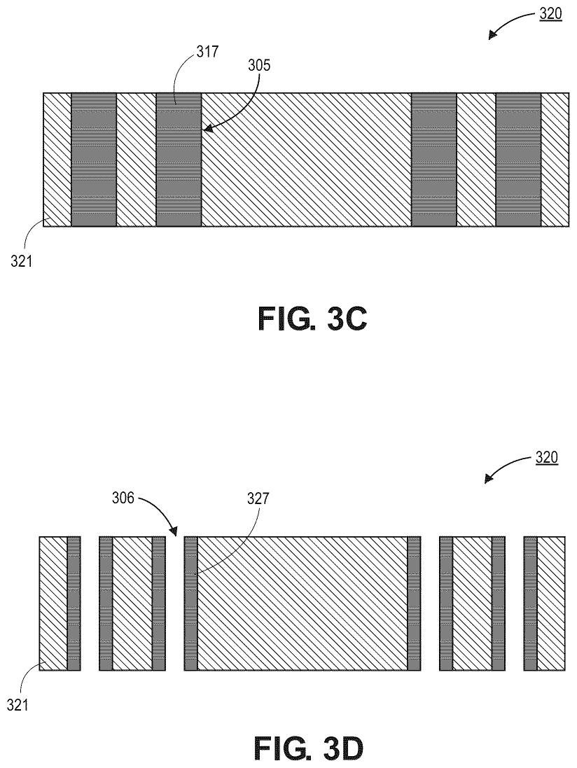

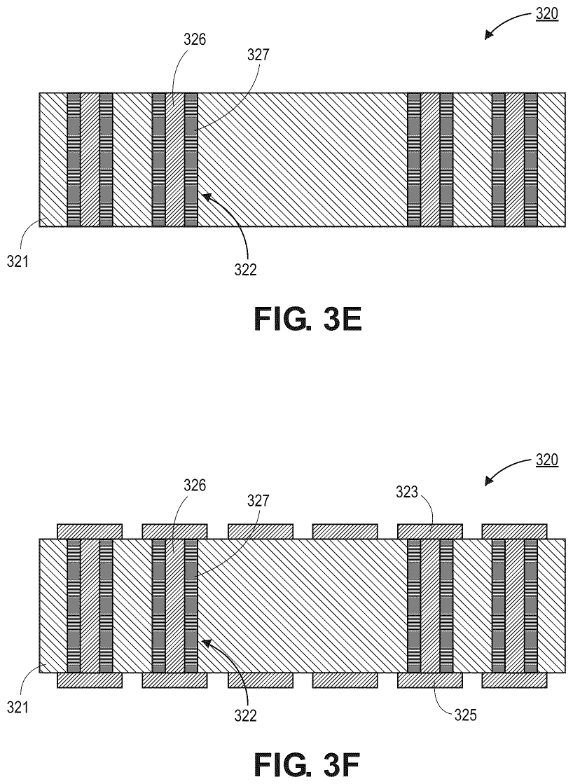

Referring now to FIGS. 3A-3F, a series of cross-sectional illustrations depicting a process for forming a bridge 320 is shown, in accordance with an embodiment. While the bridge 320 in FIGS. 3A-3F is similar to the bridge 220 in FIG. 2A, other bridge architectures may be fabricated with adjustments to the process flow.

Referring now to FIG. 3A, a cross-sectional illustration of the bridge 320 at a stage of manufacture is shown, in accordance with an embodiment. The bridge 320 comprises a substrate 321. The substrate 321 may be any material that can enable high density routing in order to couple together overlying chiplets. For example, the substrate 321 may comprise a semiconductor material (e.g., silicon), a ceramic, a glass, or the like.

Referring now to FIG. 3B, a cross-sectional illustration of the bridge 320 at a stage of manufacture is shown, in accordance with an embodiment. In an embodiment, the bridge 320 has been patterned to form openings 305. The patterning process may include a lithography and etching operation. The etching may include a dry etching process (e.g., a plasma etching operation) or a wet etching process. In other embodiments, laser ablation processes or laser assisted etching processes may be used to form the openings 305. The openings 305 may pass through an entire thickness of the substrate 321.

The openings 305 may have any suitable cross-sectional shape. For example, in FIG. 3B the openings 305 are rectangular with substantially vertical sidewalls. In other embodiments, the sidewalls of the openings 305 may be tapered, curved, non-linear, or otherwise non-orthogonal to the top and bottom surfaces of the substrate 321. The shape of the openings 305 may be at least partially dependent on the patterning process used to form the openings 305. The openings 305 may have any suitable diameter or width. In one embodiment, the width of the openings 305 may be up to approximately 100 μm. For example, the width of the openings 305 may be between approximately 10 μm and approximately 50 μm in some embodiments. Though, smaller or larger widths may also be provided for the openings 305.

Referring now to FIG. 3C, a cross-sectional illustration of the bridge 320 at a subsequent stage of manufacture is shown, in accordance with an embodiment. The bridge 320 in FIG. 3C has the openings 305 filled with a plug 317. The plug 317 may be a magnetic material. For example, the plug 317 may include a magnetic metallic material or a polymer with magnetic filler particles. The magnetic component of the plug 317 may include any material or materials with strong magnetic fields, such as those comprising iron, cobalt, nickel, neodymium, or the like. For example, the plug 317 may comprise cobalt and iron.

In an embodiment, the plugs 317 may be deposited into the openings 305 with any suitable deposition process. In some instances, the plugs 317 may be deposited with a printing or dispensing process. Other embodiments may include depositing the plugs 317 with a deposition process such as chemical vapor deposition (CVD), physical vapor deposition (PVD), or the like. Any excess magnetic material outside of the openings 305 may be removed from over the top and bottom surfaces of the substrate 321.

Referring now to FIG. 3D, a cross-sectional illustration of the bridge 320 at a subsequent stage of manufacture is shown, in accordance with an embodiment. In an embodiment, openings 306 are formed through the plugs 317. The openings 306 remove a central portion of the plugs 317 and converts the plugs 317 into shells 327. In an embodiment, the openings 306 pass entirely through a thickness of the plugs 317. In the illustrated embodiment, the openings 306 have substantially vertical sidewalls. Though, the sidewalls may have a different profiled, depending on the method of forming the openings 306.

The openings 306 may be formed with any suitable subtractive process. In one embodiment, the openings 306 may be formed with a mechanical drilling process. That is, a drill is inserted down through the plugs 317 in order to form the openings 306. A laser drilling or laser ablation process may also be used in some embodiments. Etching processes are another option that may be used in order to form the openings 306 through the plugs 317.

Referring now to FIG. 3E, a cross-sectional illustration of the bridge 320 after the vias 326 are formed is shown, in accordance with an embodiment. The vias 326 may be electrically conductive structures that are surrounded by the shells 327. The vias 326 may be formed with any suitable deposition process. For example, CVD or PVD processes may be used in order to deposit the vias 326. In other embodiments, a plating process (e.g., electroplating, electroless plating, or the like) may be used to form the vias 326. In the case of a plating process, a seed layer (not shown) may be provided over the interior surface of the shells 327 in order to initiate the metal plating. In the case of an electrically conductive shell 327, the seed layer may be omitted. Seed layers may comprise elements, such as, but not limited to, copper, titanium, platinum, palladium, or the like.

The combination of the shell 327 and the via 326 may be used to form a passive component 322. In the illustrated embodiment, the passive component 322 is an inductor. The inductors can be used in order to improve the Imax through the bridge 320 while also improving high frequency impedance issues. While the illustrated embodiment includes an inductor, other embodiments may include similar processing operations (with certain modifications) in order to form capacitor passive components.

Referring now to FIG. 3F, a cross-sectional illustration of the bridge 320 after pads 325 and 323 are formed is shown, in accordance with an embodiment. As shown, electrically conductive pads 325 may be provided on the bottom surface of the substrate 321, and electrically conductive pads 323 may be provided on the top surface of the substrate 321. The passive components 322 may provide electrical coupling between the pads 325 and the pads 323. That is, the passive components 322 may be part of the electrical path that passes vertically through a thickness of the substrate 321. In some embodiments, the passive components 322 may comprise the entire vertical path between the pads 323 and the pads 325. Other embodiments may include additional routing (e.g., vias, traces, pads, etc.) in order to make the vertical electrical connection between the pads 323 and the pads 325.

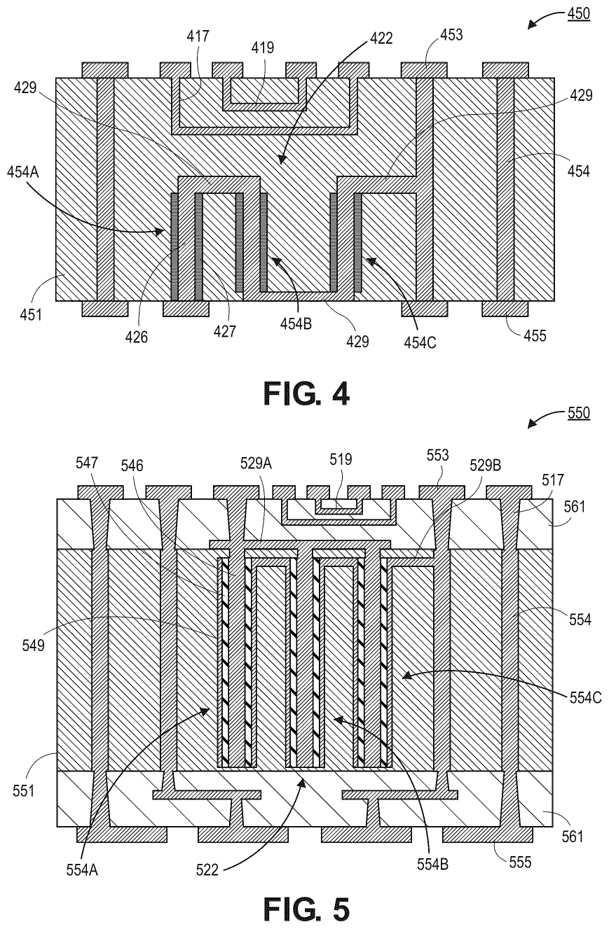

Referring now to FIG. 4, a cross-sectional illustration of a bridge 450 is shown, in accordance with an additional embodiment. The bridge 450 in FIG. 4 differs from those in previous embodiments in that the passive component 422 is formed from the combination of multiple passive elements 454A, 454B, and 454C that are linked together. For example, traces 429 provide electrical coupling between the passive elements 454 in order to connect them in series. As such, the total inductance of the passive component 422 is increased.

In an embodiment, the bridge 450 may comprise a substrate 451. The substrate 451 may be silicon or the like. For example, the material of the substrate 451 may be similar to any of the bridge substrates described in greater detail herein. In an embodiment, the bridge 450 may include pads 455 on the bottom of the substrate 451 and pads 453 on the top of the substrate 451.

In an embodiment, vias 454 may pass through the substrate 451. The vias 454 may be through silicon vias (TSVs) in some instances. The vias 454 may be standard TSV structures without any significant modification. That is, while the vias 454 may be accurately considered as being a resistor in some aspects, the vias 454 are not considered as being a passive component 422. However, it is to be appreciated that passive components 422 may include resistor structures. In such instances, the resistor structures would be different than vias 454 in that they have additional materials, non-linear paths, or any other modification that goes beyond a standard TSV structure.

The bridge 450 may also include high density routing 419 and vias 417. The high density routing 419 and vias 417 may electrically couple pads 453 together. This allows for communicatively coupling together overlying chiplets. The high density routing 419 and vias 417 may be provided in the substrate 451. In other instances, the high density routing 419 and vias 417 may be implemented in a BEOL portion of the bridge 450.

In an embodiment, the passive component 422 includes two or more passive elements 454. For example, three passive elements 454A-454C are shown in FIG. 4. The passive elements 454 may be electrically coupled to each other in series, in parallel, or in a combination of in series and in parallel. In the embodiment shown in FIG. 4, the passive elements 454A-454C are connected in series by traces 429. The passive elements 454 in FIG. 4 are inductor structures. For example, the passive elements 454 comprise an electrically conductive via 426 that is surrounded by a magnetic shell 427. The vias 426 and magnetic shell 427 may be similar in material and structure to any of the inductor based structures described in greater detail herein.

Referring now to FIG. 5, a cross-sectional illustration of a bridge 550 is shown, in accordance with an additional embodiment. The bridge 550 in FIG. 5 may include a substrate 551. The substrate 551 may be similar to any of the bridge substrates described in greater detail herein. In an embodiment, routing layers 561 may be provided above and/or below the substrate 551. The routing layers 561 may be BEOL layers with associated routing (e.g., vias 517, traces 519, etc.). Pads 555 and pads 553 may be provided under or above the routing layers 561. In an embodiments vias 554 may pass through a thickness of the substrate 551. The vias 554 may be TSVs. The vias 554 may be different than passive components 522 for reasons similar to those described above with respect to FIG. 4.

In an embodiment, the passive component 522 embedded in the substrate 551 may comprise a plurality of passive elements 554. For example, three passive elements 554A, 554B, and 554C are shown in FIG. 5. The passive elements 554 may be coupled together in any configuration, such as, in parallel, in series, or a combination of in series and in parallel. In the embodiment shown in FIG. 5, the three passive elements 554 are connected in parallel by traces 529A and 529B. The trace 529A may couple together the first electrodes 546, and the traces 529B may couple together the second electrodes 549. An interface layer 547 may electrically isolate the first electrodes 546 from the second electrodes 549. The capacitor structure and materials of passive elements 554 may be similar to any capacitor structure or materials described in greater detail herein.

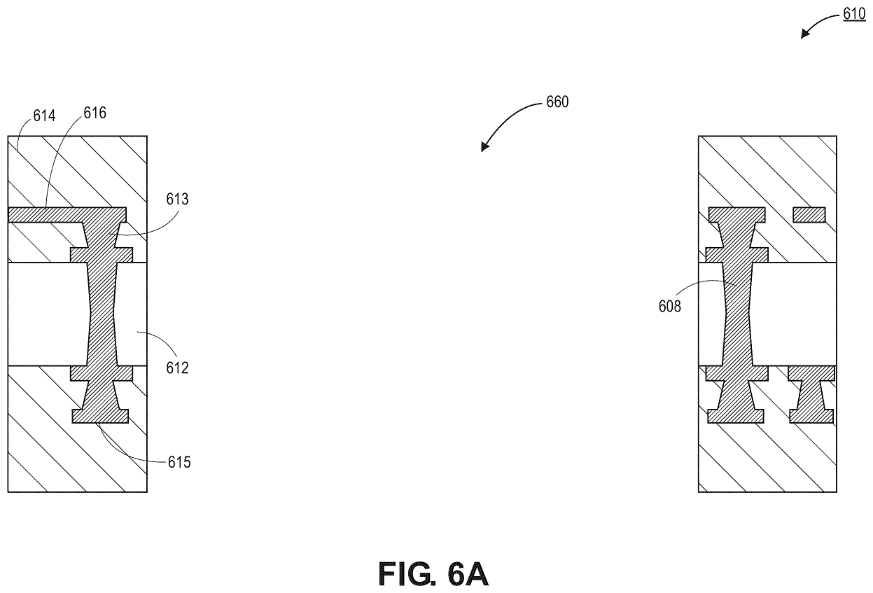

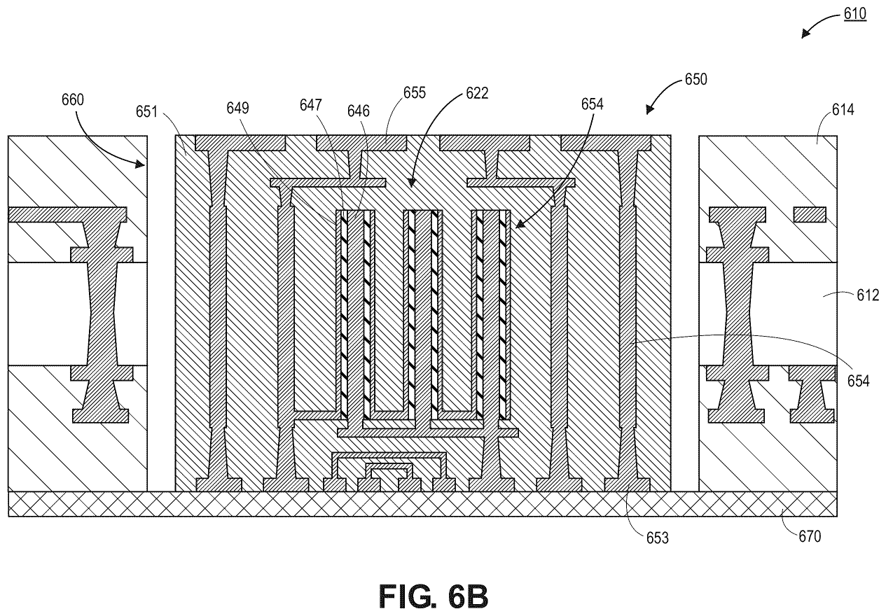

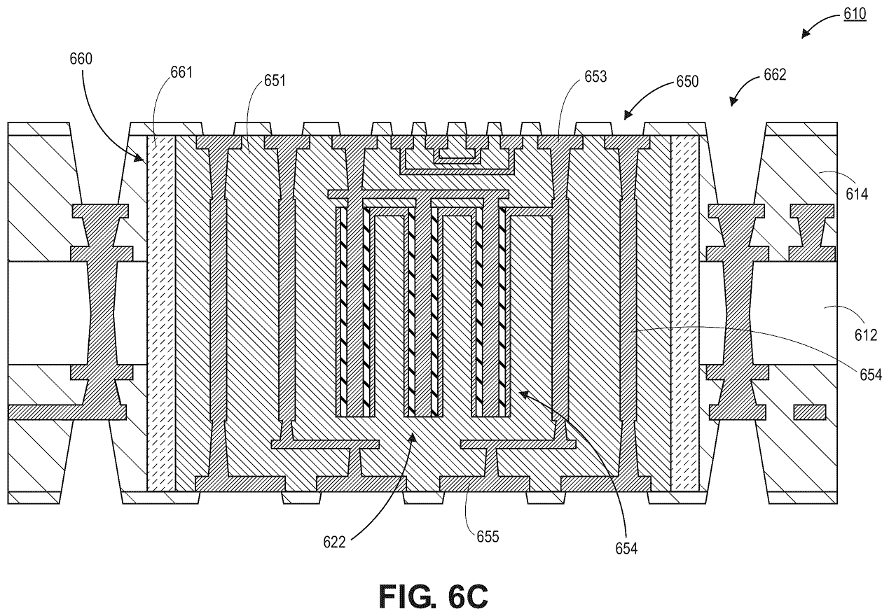

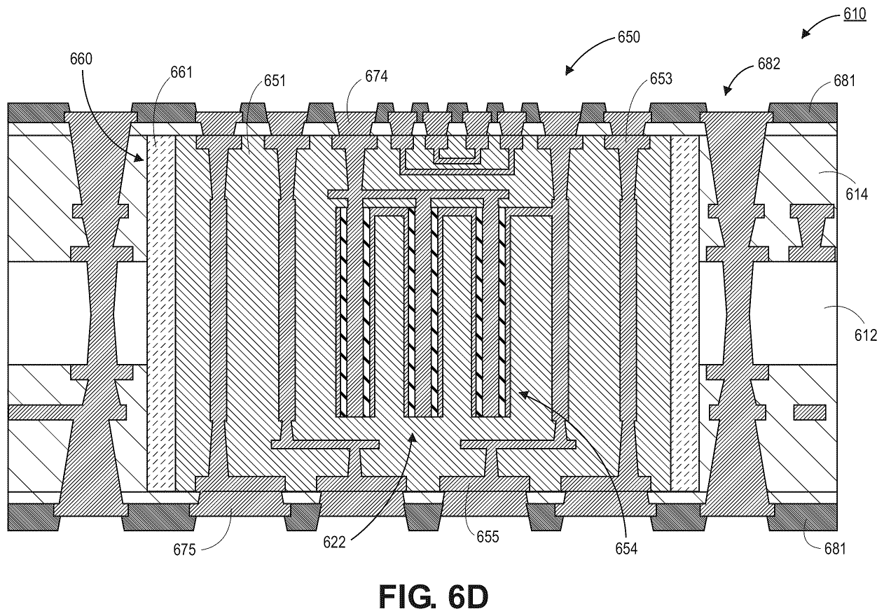

Referring now to FIGS. 6A-6D, a series of cross-sectional illustrations depicting a process for forming a package substrate 610 is shown, in accordance with an embodiment.

Referring now to FIG. 6A, a cross-sectional illustration of the package substrate 610 at a stage of manufacture is shown, in accordance with an embodiment. The package substrate 610 may comprise a core 612 with buildup layers 614 over and under the core 612. The core 612 may be a glass core or an organic core. The buildup layers 614 may be organic buildup film layers that are laminated over each other. Pads 615, vias 613, and traces 616 may be provided in the buildup layers 614. Vias 608 may be provided through the core 612. In an embodiment, an opening 660 may be provided through the package substrate 610. In an embodiment, the opening 660 passes through the buildup layers 614 and the core 612. In other embodiments, the opening 660 may pass through only a portion of the top buildup layers 614, or through only the entire top buildup layers 614.

The core 612 may be substantially all glass. The core 612 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, core 612 may be distinguished from, for example, the “prepreg” or “RF4” core of a Printed Circuit Board (PCB) substrate which typically comprises glass fibers embedded in a resinous organic material, such as an epoxy. The core 612 may have any suitable dimensions. In a particular embodiment, the core 612 may have a thickness that is approximately 50 μm or greater. For example, the thickness of the core 612 may be between approximately 50 μm and approximately 1.4 mm. Though, smaller or larger thicknesses may also be used. The core 612 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the core 612 (from an overhead plan view) may be between approximately 10 mm×10 mm and approximately 250 mm×250 mm. In an embodiment, the core 612 may have a first side that is perpendicular or orthogonal to a second side. In a more general embodiment, the core 612 may comprise a rectangular prism volume with sections (e.g., vias) removed and filled with other materials (e.g., metal, etc.).

The core 612 may comprise a single monolithic layer of glass. In other embodiments, the core 612 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the core 612 may each have a thickness less than approximately 50 μm. For example, discrete layers of glass in the core 612 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The core 612 may be any suitable glass formulation that has the necessary mechanical robustness and compatibility with semiconductor packaging manufacturing and assembly processes. For example, the core 612 may comprise aluminosilicate glass, borosilicate glass, alumino-borosilicate glass, silica, fused silica, or the like. In some embodiments, the core 612 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the core 612 may comprise silicon and oxygen, as well as any one or more of aluminum, boron, magnesium, calcium, barium, tin, sodium, potassium, strontium, phosphorus, zirconium, lithium, titanium, or zinc. In an embodiment, the core 612 may comprise at least 23 percent silicon (by weight) and at least 26 percent oxygen (by weight). In some embodiments, the core 612 may further comprise at least 5 percent aluminum (by weight).

Referring now to FIG. 6B, a cross-sectional illustration of the package substrate 610 after a bridge 650 is inserted into the opening 660 is shown, in accordance with an embodiment. In an embodiment, a tape 670 or the like may be provided across the bottom the opening 660 prior to inserting the bridge 650. The bridge 650 may be similar to any of the bridge architectures described in greater detail herein.

In the particular embodiment of FIG. 6B, the bridge 650 includes a substrate 651 with vias 654 (e.g., TSVs) between pads 653 and pads 655. An embedded passive component 622 may also be provided in the substrate 651. The passive component 622 may comprise one or more passive elements 654. In FIG. 6B, the passive elements 654 are capacitors with a first electrode 646, an interface layer 647, and a second electrode 649. The passive elements 654 may be coupled together in series, in parallel, or in a combination of in series and in parallel. In FIG. 6B, the passive elements 654 are coupled together in parallel. In other embodiments, passive elements 654 may include one or more of a capacitor, an inductor, or a resistor. The passive elements 654 may be similar to any of the passive components or passive elements described in greater detail herein.

Referring now to FIG. 6C, a cross-sectional illustration of the package substrate 610 after an additional buildup layer is formed and a fill layer 661 is provided around the bridge 650 is shown, in accordance with an embodiment. The fill layer 661 may be an epoxy, a paste, an underfill material, or the like. The fill layer 661 may fill a remainder of the opening 660 not occupied by the bridge 650. In an embodiment, via openings 662 may be provided through the buildup layers 614. The via openings 662 may be formed with a laser ablation process or the like. In some embodiments, the via openings 662 expose the pads 653 and the pads 655 of the bridge 650.

Referring now to FIG. 6D, a cross-sectional illustration of the package substrate 610 after vias/pads 674 and 675 are plated and a solder resist 681 is applied is shown, in accordance with an embodiment. The vias/pads 674 and 675 may be deposited with any suitable process, such as plating or the like. The solder resist 681 at the top and the bottom of the package substrate 610 may be patterned to form openings 682 with a laser or the like.

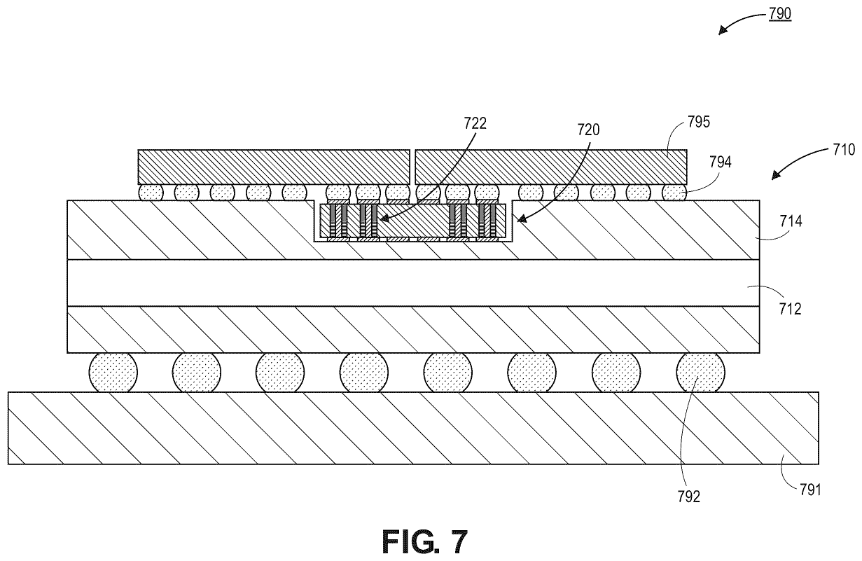

Referring now to FIG. 7, a cross-sectional illustration of an electronic system 790 is shown, in accordance with an embodiment. The electronic system 790 may comprise a board 791, such as a printed circuit board (PCB), a motherboard, or the like. The board 791 may be coupled to a package substrate 710 by interconnects 792. The interconnects 792 may be second level interconnects (SLIs), such as solder, sockets, pins, or the like.

In an embodiment, the package substrate 710 may be similar to any of the package substrates described in greater detail herein. For example, the package substrate 710 may include a core 712 (e.g., glass core or an organic core) with buildup layers 714 over and under the core 712. In an embodiment, a bridge 720 may be embedded in the package substrate 710. The bridge 720 may be similar to any bridge architecture described in greater detail herein. For example, the bridge 720 may include vias (e.g., TSVs) and one or more passive components 722. The passive components 722 may comprise passive devices, such as inductors, capacitors, resistors, or the like. The passive components 722 may be a single element, or the passive components 722 may comprise multiple elements electrically coupled in series, parallel, or series and parallel. The passive components 722 may be vertically oriented to provide a vertical electrical connection at least partially through a thickness of the bridge 720.

In an embodiment, two or more dies 795 may be coupled to the package substrate 710 by interconnects 794. The interconnects 794 may be first level interconnects (FLIs), such as solder bumps, copper bumps, hybrid bonding interfaces, or the like. The dies 795 may be communicatively coupled together by the bridge 720 in some embodiments. The dies 795 may be any type of die, such as, but not limited to, a central processing unit (CPU), a graphics processing unit (GPU), an XPU, a communications die, a memory die, an application-specific integrated circuit (ASIC), a field programmable gate array (FPGA), or the like.

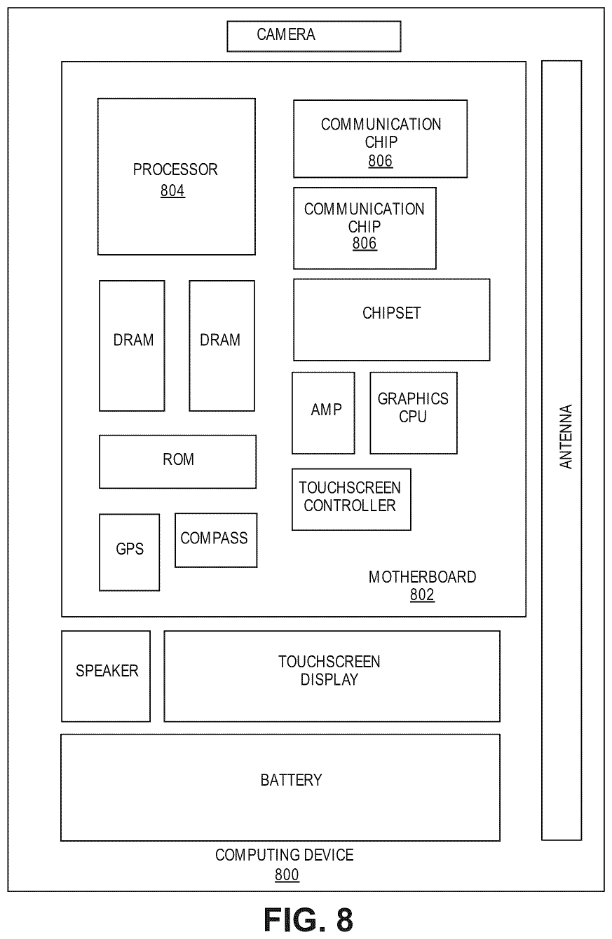

FIG. 8 illustrates a computing device 800 in accordance with one implementation of the disclosure. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the disclosure, the integrated circuit die of the processor may be part of an electronic package that includes a bridge with vertically oriented passive components, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the disclosure, the integrated circuit die of the communication chip may be part of an electronic package that includes a bridge with vertically oriented passive components, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate; a via at least partially through a thickness of the substrate, wherein the via is electrically conductive; and a shell around a perimeter of the via, wherein the shell is a different material than the via.

Example 2: the apparatus of Example 1, wherein the shell comprises a magnetic material.

Example 3: the apparatus of Example 2, wherein the shell comprises one or more of iron, cobalt, nickel, or neodymium.

Example 4: the apparatus of Examples 1-3, further comprising: a second shell around the shell, wherein the second shell is electrically conductive.

Example 5: the apparatus of Example 4, wherein the shell comprises a material with a dielectric constant higher than approximately 3.9.

Example 6: the apparatus of Examples 1-5, wherein a thickness of the shell between an inner surface and an outer surface is at least approximately 1 μm.

Example 7: the apparatus of Examples 1-6, wherein the via has vertical sidewalls.

Example 8: the apparatus of Examples 1-7, wherein the via has sloped sidewalls.

Example 9: the apparatus of Examples 1-8, wherein the substrate comprises silicon.

Example 10: the apparatus of Examples 1-9, further comprising: a second via at least partially through a thickness of the substrate, wherein an outer surface of the second via contacts the substrate.

Example 11: an apparatus, comprising: a substrate; a cavity into the substrate; and a die inserted at least partially into the cavity, wherein the die comprises: a via through a thickness of the die; and an electrically passive component embedded in the die, wherein the electrically passive component is at least part of an electrical path between a top of the die and a bottom of the die.

Example 12: the apparatus of Example 11, wherein the electrically passive component is an inductor.

Example 13, the apparatus of Example 11, wherein the electrically passive component is a capacitor.

Example 14: the apparatus of Examples 11-13, wherein the electrically passive component comprises a second via that is electrically conductive and a shell around the second via.

Example 15: the apparatus of Example 14, wherein the shell comprises one or more of iron, cobalt, nickel, or neodymium.

Example 16: the apparatus of Examples 11-15, wherein the substrate is an organic dielectric layer, and wherein the substrate is over a solid glass layer.

Example 17: an apparatus, comprising: a board; a package substrate over the board, wherein the package substrate comprises: a dielectric substrate with a cavity; and a bridge die in the cavity, wherein the bridge die includes a via through a thickness of the bridge die and one or both of an inductor or a capacitor embedded in the bridge die; and a die over the package substrate.

Example 18: the apparatus of Example 17, wherein the inductor or the capacitor comprise an electrically conductive second via and a shell around the electrically conductive second via.

Example 19: the apparatus of Example 17 or Example 18, wherein the package substrate comprises a glass core, wherein the glass core is a solid glass layer with a rectangular prism form factor.

Example 20: the apparatus of Examples 17-19, wherein the apparatus is part of a personal computer, a server, a mobile device, a tablet, or an automobile.

What is claimed is:

1. An apparatus, comprising:
a substrate;
a via at least partially through a thickness of the substrate, wherein the via is electrically conductive; and
a shell around a perimeter of the via, wherein the shell is a different material than the via.

2. The apparatus of claim 1, wherein the shell comprises a magnetic material.

3. The apparatus of claim 2, wherein the shell comprises one or more of iron, cobalt, nickel, or neodymium.

4. The apparatus of claim 1, further comprising:
a second shell around the shell, wherein the second shell is electrically conductive.

5. The apparatus of claim 4, wherein the shell comprises a material with a dielectric constant higher than approximately 3.9.

6. The apparatus of claim 1, wherein a thickness of the shell between an inner surface and an outer surface is at least approximately 1 μm.

7. The apparatus of claim 1, wherein the via has vertical sidewalls.

8. The apparatus of claim 1, wherein the via has sloped sidewalls.

9. The apparatus of claim 1, wherein the substrate comprises silicon.

10. The apparatus of claim 1, further comprising:
a second via at least partially through a thickness of the substrate, wherein an outer surface of the second via contacts the substrate.

11. An apparatus, comprising:
a substrate;
a cavity into the substrate; and
a die inserted at least partially into the cavity, wherein the die comprises:
a via through a thickness of the die; and
an electrically passive component embedded in the die, wherein the electrically passive component is at least part of an electrical path between a top of the die and a bottom of the die.

12. The apparatus of claim 11, wherein the electrically passive component is an inductor.

13. The apparatus of claim 11, wherein the electrically passive component is a capacitor.

14. The apparatus of claim 11, wherein the electrically passive component comprises a second via that is electrically conductive and a shell around the second via.

15. The apparatus of claim 14, wherein the shell comprises one or more of iron, cobalt, nickel, or neodymium.

16. The apparatus of claim 11, wherein the substrate is an organic dielectric layer, and wherein the substrate is over a solid glass layer.

17. An apparatus, comprising:
a board;
a package substrate over the board, wherein the package substrate comprises:
a dielectric substrate with a cavity; and
a bridge die in the cavity, wherein the bridge die includes a via through a thickness of the bridge die and one or both of an inductor or a capacitor embedded in the bridge die; and
a die over the package substrate.

18. The apparatus of claim 17, wherein the inductor or the capacitor comprise an electrically conductive second via and a shell around the electrically conductive second via.

19. The apparatus of claim 17, wherein the package substrate comprises a glass core, wherein the glass core is a solid glass layer with a rectangular prism form factor.

20. The apparatus of claim 17, wherein the apparatus is part of a personal computer, a server, a mobile device, a tablet, or an automobile.
